(19) United States
(12) Patent Application Publication
(10) Pub. No.: US 2025/0212459 A1
(43) Pub. Date: Jun. 26, 2025

(54) METALLIC SOURCE/DRAIN WITH STRESS FOR ADVANCED LOGIC TRANSISTORS

(71) Applicant: Applied Materials, Inc., Santa Clara, CA (US)

(72) Inventors: Nicolas BREIL, San Jose, CA (US); Benjamin COLOMBEAU, San Jose, CA (US); Balasubramanian PRANATHARTHIHARAN, San Jose, CA (US); Pratik VYAS, Fremont, CA (US); Ashish PAL, San Ramon, CA (US); El Mehdi BAZIZI, San Jose, CA (US)

(73) Assignee: Applied Materials, Inc., Santa Clara, CA (US)

(21) Appl. No.: 18/391,056

(22) Filed: Dec. 20, 2023

(51) Int. Cl. H01L 29/423; H01L 21/8238; H01L 27/092; H01L 29/66; H01L 29/78; H01L 29/786

(52) U.S. Cl. CPC H10D 30/6735; H10D 30/024; H10D 30/62; H10D 30/6757; H10D 64/017; H10D 64/018; H10D 84/0167; H10D 84/0172; H10D 84/0193; H10D 84/038; H10D 84/853

(57) ABSTRACT

A system and method for fabricating a gate all-around (GAA) field effect transistor (FET) is disclosed. The method includes: forming a plurality of epitaxy layers on a substrate, wherein a formed epitaxy layer includes a plurality of doped channels, a plurality of metal channels, and a dummy gate; depositing a spacer in a source/drain cavity, wherein at least a portion of the spacer is deposited on a dummy gate of a formed epitaxy layer; partially etching the plurality of metal channels of to create a plurality of voids; depositing an inner spacer in each void of the plurality of voids; and depositing a stressed metal filler in the source/drain cavity.

### TECHNICAL FIELD

The present disclosure relates generally to gate all-around (GAA) logic devices, and specifically to improving source-drain drive current in GAA logic devices.

### BACKGROUND

CMOS technology has evolved from planar based technologies to FinFET technology. The next generation of field effect transistors (FETs) which is becoming available as high volume manufacturing (HVM) is known as gate all-around (GAA) devices. As the industry continues scaling, and for overall circuit and chip level performance enhancement, a typical target requirement is for 10% drive current improvement from GAA generation to generation.

For the next GAA generations (or nodes), the semiconductor industry needs to come up with techniques for drive current boosting. Towards this, the industry is currently working towards developing a metallic source/drain concept where part of the silicon epitaxy region is replaced with metals. Since metals are typically of higher conductivity than that of silicon, the metallic source/drain reduces overall device resistance and thus increases drive current.

It would therefore be advantageous to provide a solution that would improve the challenges noted above.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “some embodiments” or “certain embodiments” may be used herein to refer to a single embodiment or multiple embodiments of the disclosure.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

In one general aspect, method may include forming a plurality of epitaxy layers on a substrate, where a formed epitaxy layer includes a plurality of doped channels, a plurality of metal channels, and a dummy gate. Method may also include depositing a spacer in a source/drain cavity, where at least a portion of the spacer is deposited on a dummy gate of a formed epitaxy layer. Method may furthermore include partially etching the plurality of metal channels of to create a plurality of voids. Method may in addition include depositing an inner spacer in each void of the plurality of voids. Method may moreover include depositing a stressed metal filler in the source/drain cavity. Other embodiments of this aspect include corresponding computer systems, apparatus, and computer programs recorded on one or more computer storage devices, each configured to perform the actions of the methods.

Implementations may include one or more of the following features. Method where forming the plurality of epitaxy layers further comprises: depositing a plurality of layers including a plurality of doped channels and a plurality of metal channels; and etching the plurality of layers to isolate a first plurality of epitaxy layers from a second plurality of epitaxy layers. Method may include: depositing the stressed metal filler to include any one of: a tensile stress, and a compressive stress. Method may include: depositing a dummy polygate on the epitaxy layer; depositing a hard mask on the dummy polygate; and further depositing the spacer on the hard mask, such that the spacer insulates the stressed metal filler from: an epitaxy layer, the dummy polygate, and the hard mask. Method may include: fabricating a complementary GAA FET, including a first epitaxy layer and a second epitaxy layer; and depositing a first stressed metal filler corresponding to the first epitaxy layer, and a second stressed metal filler corresponding to the second epitaxy layer. Implementations of the described techniques may include hardware, a method or process, or a computer tangible medium.

In one general aspect, a GAA FET device may include a plurality of epitaxy layers deposited on a substrate, where an epitaxy layer includes a plurality of doped channels, a plurality of metal channels, and a dummy gate. GAA FET device may also include a spacer deposited in a source/drain cavity, where at least a portion of the spacer is deposited on a dummy gate of a formed epitaxy layer. GAA FET device may furthermore include a plurality of voids fabricated by partially etching the plurality of metal channels. GAA FET device may in addition include an inner spacer deposited in each void of the plurality of voids. GAA FET device may moreover include a stressed metal filler deposited in the source/drain cavity. Other embodiments of this aspect include corresponding computer systems, apparatus, and computer programs recorded on one or more computer storage devices, each configured to perform the actions of the methods.

Implementations may include one or more of the following features. GAA FET device where forming the plurality of epitaxy layers further comprises: depositing a plurality of layers including a plurality of doped channels and a plurality of metal channels; and etching the plurality of layers to isolate a first plurality of epitaxy layers from a second plurality of epitaxy layers. GAA FET device where the stressed metal filler is deposited to include a tensile stress. GAA FET device where the stressed metal filler is deposited to include a compressive stress. GAA FET device may include: a dummy polygate deposited on the epitaxy layer; a hard mask deposited on the dummy polygate; and where the spacer is deposited on the hard mask, such that the spacer insulates the stressed metal filler from: an epitaxy layer, the dummy polygate, and the hard mask. GAA FET may include: a complementary GAA FET, including a first epitaxy layer and a second epitaxy layer; a first stressed metal filler corresponding to the first epitaxy layer; and a second stressed metal filler corresponding to the second epitaxy layer. Implementations of the described techniques may include hardware, a method or process, or a computer tangible medium.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 is an example isometric view of an illustration of a first step of a metallic stress FinFET manufacturing process, implemented in accordance with an embodiment.

FIG. 2 is an example isometric view of an illustration of a second step of a metallic stress FinFET manufacturing process, implemented in accordance with an embodiment.

FIG. 3 is an example isometric view of an illustration of a third step of a metallic stress FinFET manufacturing process, implemented in accordance with an embodiment.

FIG. 4 is an example isometric view of an illustration of a fourth step of a metallic stress FinFET manufacturing process, implemented in accordance with an embodiment.

FIG. 5 is an example flowchart of a method for fabricating a gate all-around (GAA) device having an increased mobility and drive-current, implemented in accordance with an embodiment.

FIG. 6 is an example graph of measured stress in a field effect transistor having stress transferred from a stressed metal filler to a channel, utilized to describe an embodiment.

FIG. 7 is an example graph of drive current as a function of average compressive channel strength, utilized to describe an embodiment.

FIG. 8 is an example schematic diagram of a system for controlling a fabrication process for a wafer including a GAA with stressed metallic S/D cavity fill, according to an embodiment.

### DETAILED DESCRIPTION

It is important to note that the embodiments disclosed herein are only examples of the many advantageous uses of the innovative teachings herein. In general, statements made in the specification of the present application do not necessarily limit any of the various claimed embodiments. Moreover, some statements may apply to some inventive features but not to others. In general, unless otherwise indicated, singular elements may be in plural and vice versa with no loss of generality. In the drawings, like numerals refer to like parts through several views.

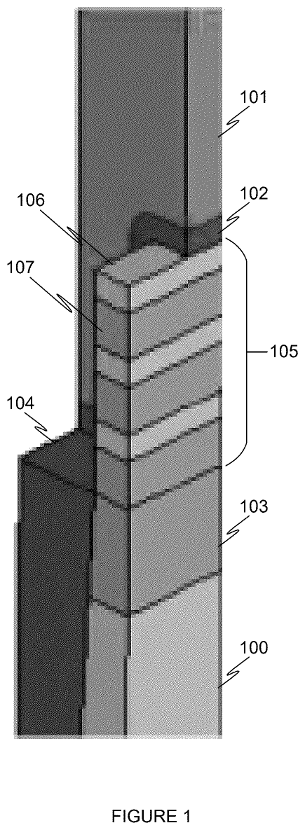

FIG. 1 is an example isometric view of an illustration of a first step of a metallic stress FinFET manufacturing process, implemented in accordance with an embodiment.

According to an embodiment, a manufacture process of a FinFET device includes manufacturing a dummy gate including an epitaxy layer 105. In an embodiment, the epitaxy later includes a plurality of MOS channels, such as NMOS channel 106, and a plurality of metal channels, such as metal channel 107. In some embodiments, the epitaxy layer 105 is stacked such that a first MOS channel (such as NMOS channel 106) is fabricated between a first metal channel (e.g., metal channel 107) and a second metal channel.

In some embodiments, the epitaxy layer 105 is partially covered by a spacer layer 102. In an embodiment, the spacer layer 102 is a dielectric layer. In some embodiments, the epitaxy layer 105 is partially covered by the spacer layer 102 and partially exposed.

In an embodiment, a portion of the epitaxy layer 105 extends on the silicon layer 103 deposited on substrate 100. In certain embodiments, the portion of the epitaxy layer 105 which is not covered by the spacer layer 102 is known as a dummy gate.

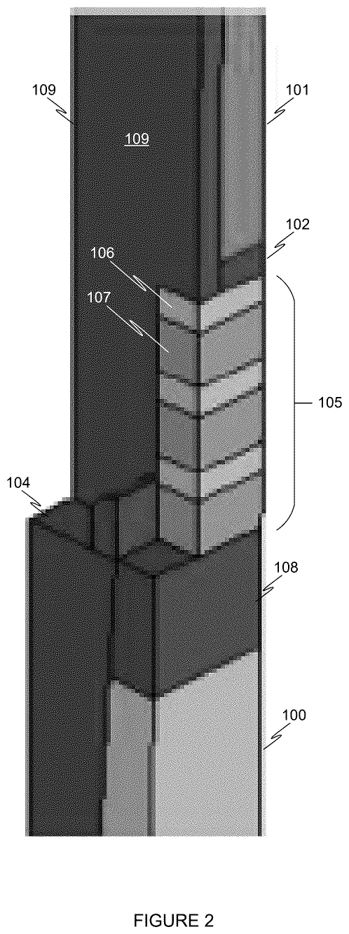

FIG. 2 is an example isometric view of an illustration of a second step of a metallic stress FinFET manufacturing process, implemented in accordance with an embodiment. In an embodiment, the dummy gate, i.e., the portion of the epitaxy layer 105 which is exposed, is covered with a spacer 109.

In some embodiments, a portion of the dummy gate is etched away, for example by reactive ion etching, and the spacer 109 is fabricated over the remaining dummy gate. In an embodiment, the spacer 109 is an electric insulator, such as tri-silicon tetranitride (Si3N4).

In certain embodiments, the silicon layer 103 is etched out, and a silicon insulator 108 is deposited on the substrate 100, for example to create a shallow trench insulator (STI).

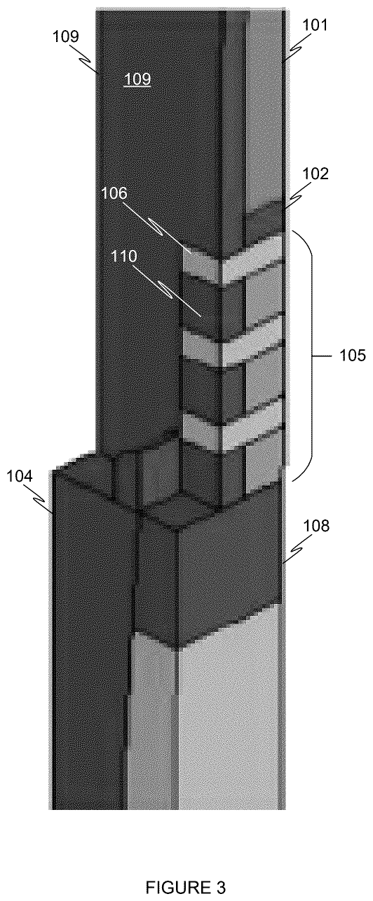

FIG. 3 is an example isometric view of an illustration of a third step of a metallic stress FinFET manufacturing process, implemented in accordance with an embodiment. In an embodiment, a portion of the dummy gate is etched away. In an embodiment, only the metal channels of the epitaxy layer 105 are etched in the dummy gate portion. In some embodiments, etching is achieved utilizing reactive ion etching.

In certain embodiments, an inner spacer 110 is deposited in place of the etched channel. In an embodiment, the inner spacer 110 is deposited utilizing atomic layer deposition (ALD). In some embodiments, the inner spacer 110 provides electric insulation between the epitaxy layer 105 and a metallic stressed fill deposited in the source/drain cavity.

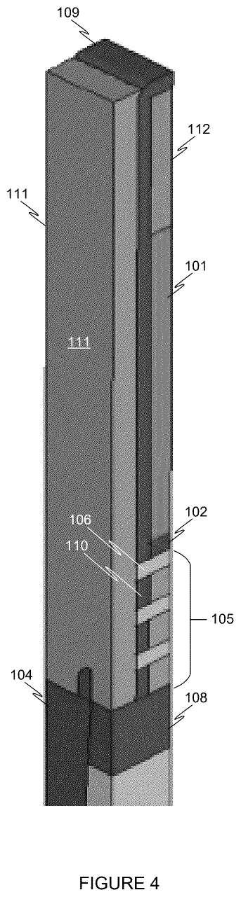

FIG. 4 is an example isometric view of an illustration of a fourth step of a metallic stress FinFET manufacturing process, implemented in accordance with an embodiment. In an embodiment, the source/drain cavity is filled with a stressed metal 111.

In certain embodiments, a dummy polygate 101 is fabricated over the spacer 102. In some embodiments, a hard mask 112 is deposited over the dummy polygate 101. In an embodiment, the spacer 109 is deposited to cover the hard mask 112.

In an embodiment, the metallic filler 111 is deposited to include built-in stress. In some embodiments, depositing the metallic filler 111 transfers stress from the metallic filler 111 to the channel between the source and drain. In an embodiment, this results in incorporation of channel stress from the metallic source/drain (i.e., the metallic filler 111).

According to some embodiments, incorporating channel stress from the metallic filler 111 into the channel modifies the channel mobility and transistor drive-current. In an embodiment, the metallic filler 111 is deposited to include tensile stress, compressive stress, and the like.

For example, in some embodiments, in an NMOS gate all-around (GAA) transistor, a tensile channel stress leads to mobility improvement and increase in drive-current. In certain embodiments, a compressive channel stress leads to mobility improvement and drive-current increase in a PMOS GAA.

In some embodiments, a complementary field effect transistor (CFET) device includes a complementary pair of MOS devices, such as an NMOS device and a PMOS device. In some embodiments, the PMOS device is deposited on the bottom of the CFET (i.e., closer to the substrate), with the NMOS device deposited on top of the PMOS device.

In an embodiment, the metallic filler 111 is deposited only for the PMOS device, filling only the portion of the source-drain cavity which is inhabited by the PMOS device. In an embodiment, this fabrication allows to increase mobility and drive-current in the PMOS device only, which has lower mobility and drive-current compared to an NMOS device.

In certain embodiments, for example where fabricating a stacked CFET device (i.e., stacking a plurality of CFETs on top of each other) a metallic filler 111 is deposited at various stages, for example to deposit a first metallic filler with a compressive stress for a first PMOS device. In an embodiment, an insulator is deposited on the first metallic filler, the insulator corresponding to an NMOS device. In an embodiment, a second metallic filler is deposited in place of the insulator. For example, in an embodiment, the second metallic filler is deposited to include a tensile stress.

In some embodiments, a third metallic filler is deposited on top of the insulator (or second metallic filler) to correspond to a second PMOS device. In an embodiment, the third metallic filler includes a tensile stress. In some embodiments, an insulator, or a fourth metallic filler, is deposited on top of the third metallic filler. In an embodiment, the fourth metallic filler includes a tensile stress. In other embodiments, the metallic filler 111 is provided to an entire FET, CFET, stacked CFET, and the like structures.

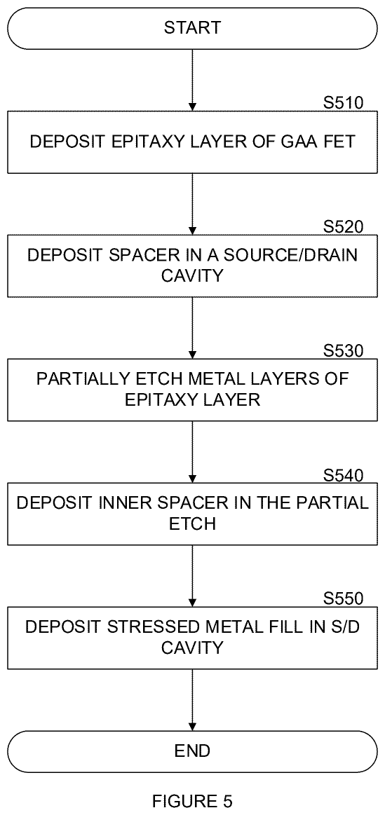

FIG. 5 is an example flowchart of a method for fabricating a gate all-around (GAA) device having an increased mobility and drive-current, implemented in accordance with an embodiment.

At S510, an epitaxy layer is deposited on a substrate. In an embodiment, the epitaxy layer includes a plurality of doped channels, such as n-channels, or p-channels. In certain embodiments, depositing a plurality of n-channels results in fabricating an NMOS device, and depositing a plurality of p-channels results in fabricating a PMOS device.

In an embodiment, the epitaxy layer includes a plurality of metal channels, such that at least a portion of the doped channels (i.e., each n-channel or each p-channel) is deposited between two metal channels.

In some embodiments, a plurality of epitaxy layers are deposited as a stack on the substrate, such that a first epitaxy layer is deposited on top of the substrate, and a second epitaxy layer is deposited on top of the first epitaxy layer. In some embodiments, each epitaxy layer is separated from another epitaxy layer by an insulator, deposited thereon.

In certain embodiments, where a plurality of epitaxy layers are deposited, the plurality of layers are deposited in a complementary fashion, such that a device fabricated from a first epitaxy layer is complementary to a device below (or above) in the epitaxy layers stack. For example, in an embodiment, a first epitaxy layer is utilized in fabricating a PMOS device and a second epitaxy layer deposited above the first epitaxy layer is utilized in fabricating an NMOS device.

At S520, an insulating spacer is deposited in a source/drain cavity. In an embodiment, the insulating spacer is deposited in an S/D (source/drain) cavity on top of a dummy gate. According to an embodiment, the spacer is an electrically insulating material, such as tri-silicon tetranitride (Si3N4). In some embodiments, the insulating spacer is deposited using an atomic layer deposition technique.

In certain embodiments, an insulator is deposited above the epitaxy layer. In some embodiments, a dummy polygate is deposited over the insulator which is deposited above the epitaxy layer. In some embodiments, where there are a plurality of epitaxy layers, the insulator is deposited above the top epitaxy layer. In an embodiment, the insulator is deposited between the dummy polygate and the epitaxy layer.

At S530, the epitaxy layer is etched. In an embodiment, the metal channels of the epitaxy layer are etched, partially etched, etc., to remove a portion of each metal channel. In an embodiment, this results in a plurality of voids between the plurality of doped channels of the epitaxy layer.

In an embodiment, the metal channels of the epitaxy layer are etched away by reactive ion etching.

At S540, an inner spacer is deposited. In an embodiment, a plurality of inner spacers are deposited, each inner spacer deposited in the void resulting from an etching of the epitaxy layer.

According to an embodiment, the inner spacer and the insulating spacer are both electrically insulating materials. In some embodiments, the inner spacers are deposited by atomic layer deposition. In certain embodiments, an additional etching step is utilized to clean any excess material in case of over-deposition of the insulating inner spacers.

At S550, a stressed metal fill is deposited. In an embodiment, the stressed metal fill is deposited in the S/D cavity. In some embodiments, the metal fill includes a predetermined stress. For example, according to an embodiment, the metal fill includes a compressive stress, a tensile stress, and the like.

In some embodiments, a plurality of stressed metal fillers are utilized. For example, according to an embodiment, a first stressed metal filler is utilized for a first MOS device type, and a second stressed metal filler is utilized for a second, different, MOS device type.

For example, in an embodiment, the first stressed metal filler includes a tensile stress, and the first type of MOS device is an NMOS device. In some embodiments, the second stressed metal filler includes a compressive stress, and the second type of the MOS device is a PMOS device.

In certain embodiments, a complementary FET (CFET) device is fabricated including a first PMOS and a first NMOS device stacked on top of each other. In an embodiment, each device of the CFET has a metal filler deposited adjacent thereto, according to a requirement of the device.

For example, in an embodiment, a metal filler having a compressive stress is deposited adjacent to the PMOS device in the CFET stack, and a metal filler having a tensile stress is deposited adjacent to the NMOS device in the CFET stack. In an embodiment, the PMOS device is deposited on top of the NMOS device, and the metal filler having the compressive stress is deposited on top of the metal filler having the tensile stress.

In some embodiments, the total height of the stressed metal filler is equal to, or less than, the height of the FinFET device, for example between 15 nm to 40 nm. In certain embodiments, the width of the metallic filler is approximately 9 nm. In an embodiment, the metal filler includes an internal stress of approximately 1 GPa.

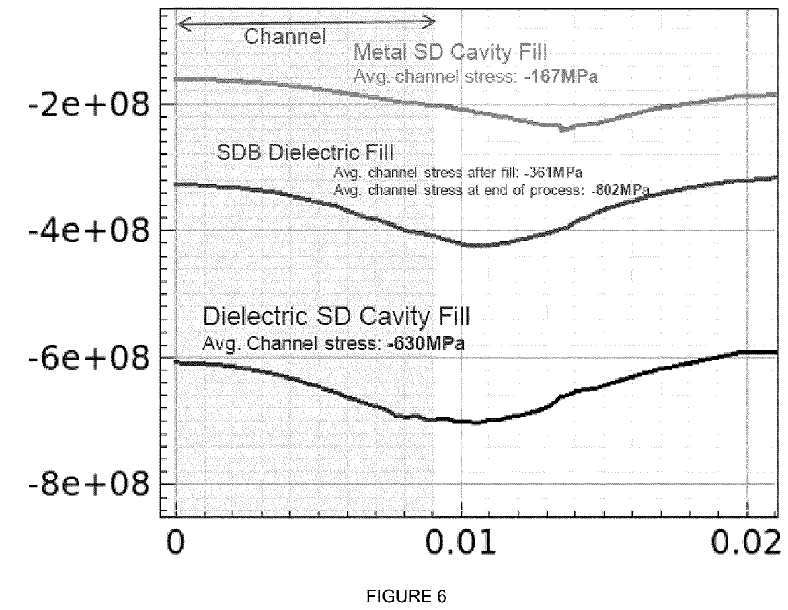

FIG. 6 is an example graph of measured stress in a field effect transistor having stress transferred from a stressed metal filler to a channel, utilized to describe an embodiment. The graph includes a measure of stress at various points on the channel, including a measurement of stress of a channel having a dielectric fill in the S/D cavity measuring an average channel stress of −630 MPa, a measurement of stress of a channel having a single diffusion break (SDB) having an average channel stress of −316 MPa, and a measurement of stress of a channel having a stressed metal S/D cavity fill, having an average channel stress measurement of −167 MPa.

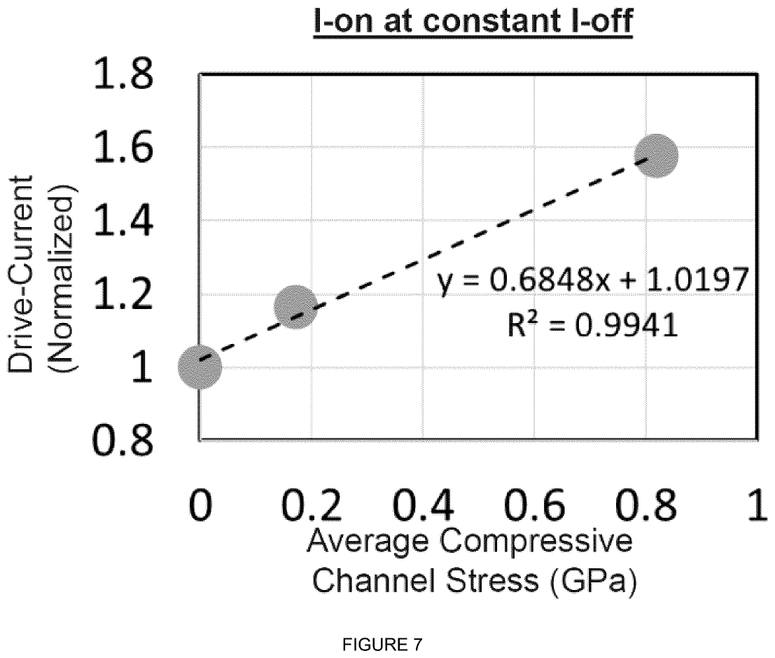

FIG. 7 is an example graph of drive current as a function of average compressive channel strength, utilized to describe an embodiment. According to an embodiment, drive current is measured in channels having different compressive stress measurements. In an embodiment, the graph shows that a drive-current improvement of between 10-20% is evident when utilizing a metallic filler in the S/D cavity including a stress which transfers to the channel, thereby improving the drive-current.

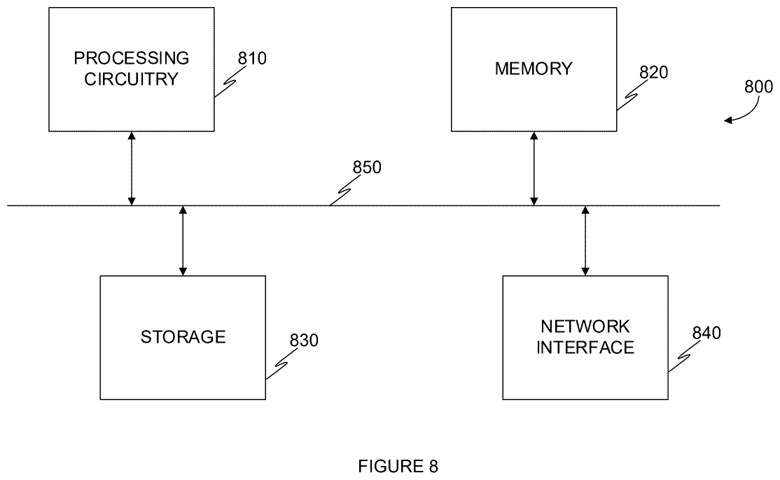

FIG. 8 is an example schematic diagram of a system 800 for controlling a fabrication process for a wafer including a GAA with stressed metallic S/D cavity fill, according to an embodiment. The system 800 includes, according to an embodiment, a processing circuitry 810 coupled to a memory 820, a storage 830, and a network interface 840. In an embodiment, the components of the system 800 are communicatively connected via a bus 850.

In certain embodiments, the processing circuitry 810 is realized as one or more hardware logic components and circuits. For example, according to an embodiment, illustrative types of hardware logic components include field programmable gate arrays (FPGAs), application-specific integrated circuits (ASICs), Application-specific standard products (ASSPs), system-on-a-chip systems (SOCs), graphics processing units (GPUs), tensor processing units (TPUs), Artificial Intelligence (AI) accelerators, general-purpose microprocessors, microcontrollers, digital signal processors (DSPs), and the like, or any other hardware logic components that are configured to perform calculations or other manipulations of information.

In an embodiment, the memory 820 is a volatile memory (e.g., random access memory, etc.), a non-volatile memory (e.g., read only memory, flash memory, etc.), a combination thereof, and the like. In some embodiments, the memory 820 is an on-chip memory, an off-chip memory, a combination thereof, and the like. In certain embodiments, the memory 820 is a scratch-pad memory for the processing circuitry 810.

In one configuration, software for implementing one or more embodiments disclosed herein is stored in the storage 830, in the memory 820, in a combination thereof, and the like. Software shall be construed broadly to mean any type of instructions, whether referred to as software, firmware, middleware, microcode, hardware description language, or otherwise. Instructions include, according to an embodiment, code (e.g., in source code format, binary code format, executable code format, or any other suitable format of code). The instructions, when executed by the processing circuitry 810, cause the processing circuitry 810 to perform the various processes described herein, in accordance with an embodiment.

In some embodiments, the storage 830 is a magnetic storage, an optical storage, a solid-state storage, a combination thereof, and the like, and is realized, according to an embodiment, as a flash memory, as a hard-disk drive, another memory technology, various combinations thereof, or any other medium which can be used to store the desired information.

The network interface 840 is configured to provide the system 800 with communication with, for example, additional components of the fabrication process, according to an embodiment.

It should be understood that the embodiments described herein are not limited to the specific architecture illustrated in FIG. 8, and other architectures may be equally used without departing from the scope of the disclosed embodiments.

The various embodiments disclosed herein can be implemented as hardware, firmware, software, or any combination thereof. Moreover, the software is preferably implemented as an application program tangibly embodied on a program storage unit or computer readable medium consisting of parts, or of certain devices and/or a combination of devices. The application program may be uploaded to, and executed by, a machine comprising any suitable architecture. Preferably, the machine is implemented on a computer platform having hardware such as one or more processing units (“PUs”), a memory, and input/output interfaces. The computer platform may also include an operating system and microinstruction code. The various processes and functions described herein may be either part of the microinstruction code or part of the application program, or any combination thereof, which may be executed by a PU, whether or not such a computer or processor is explicitly shown. In addition, various other peripheral units may be connected to the computer platform such as an additional data storage unit and a printing unit. Furthermore, a non-transitory computer readable medium is any computer readable medium except for a transitory propagating signal.

All examples and conditional language recited herein are intended for pedagogical purposes to aid the reader in understanding the principles of the disclosed embodiment and the concepts contributed by the inventor to furthering the art, and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A method for fabricating a gate all-around (GAA) field effect transistor (FET), comprising:
forming a plurality of epitaxy layers on a substrate, wherein a formed epitaxy layer includes a plurality of doped channels, a plurality of metal channels, and a dummy gate;
depositing a spacer in a source/drain cavity, wherein at least a portion of the spacer is deposited on a dummy gate of a formed epitaxy layer;
partially etching the plurality of metal channels of to create a plurality of voids;
depositing an inner spacer in each void of the plurality of voids; and
depositing a stressed metal filler in the source/drain cavity.

2. The method of claim 1, wherein forming the plurality of epitaxy layers further comprises:
depositing a plurality of layers including a plurality of doped channels and a plurality of metal channels; and
etching the plurality of layers to isolate a first plurality of epitaxy layers from a second plurality of epitaxy layers.

3. The method of claim 1, further comprising:
depositing the stressed metal filler to include any one of: a tensile stress, and a compressive stress.

4. The method of claim 1, further comprising:
depositing a dummy polygate on the epitaxy layer;
depositing a hard mask on the dummy polygate; and
further depositing the spacer on the hard mask, such that the spacer insulates the stressed metal filler from: an epitaxy layer, the dummy polygate, and the hard mask.

5. The method of claim 1, further comprising:
fabricating a complementary GAA FET, including a first epitaxy layer and a second epitaxy layer; and
depositing a first stressed metal filler corresponding to the first epitaxy layer, and a second stressed metal filler corresponding to the second epitaxy layer.

6. A gate all-around (GAA) field effect transistor (FET) device, comprising:
a plurality of epitaxy layers deposited on a substrate, wherein an epitaxy layer includes a plurality of doped channels, a plurality of metal channels, and a dummy gate;
a spacer deposited in a source/drain cavity, wherein at least a portion of the spacer is deposited on a dummy gate of a formed epitaxy layer;
a plurality of voids fabricated by partially etching the plurality of metal channels;
an inner spacer deposited in each void of the plurality of voids; and
a stressed metal filler deposited in the source/drain cavity.

7. The GAA FET device of claim 6, wherein forming the plurality of epitaxy layers further comprises:
depositing a plurality of layers including a plurality of doped channels and a plurality of metal channels; and
etching the plurality of layers to isolate a first plurality of epitaxy layers from a second plurality of epitaxy layers.

8. The GAA FET device of claim 6, wherein the stressed metal filler is deposited to include a tensile stress.

9. The GAA FET device of claim 6, wherein the stressed metal filler is deposited to include a compressive stress.

10. The GAA FET device of claim 6, further comprising:
a dummy polygate deposited on the epitaxy layer;
a hard mask deposited on the dummy polygate; and
wherein the spacer is deposited on the hard mask, such that the spacer insulates the stressed metal filler from: an epitaxy layer, the dummy polygate, and the hard mask.

11. The GAA FET of claim 6, further comprising:
a complementary GAA FET, including a first epitaxy layer and a second epitaxy layer;
a first stressed metal filler corresponding to the first epitaxy layer; and
a second stressed metal filler corresponding to the second epitaxy layer.
